(19) United States
(12) Patent Application Publication
(10) Pub. No.: US 2009/0097087 A1
(43) Pub. Date: Apr. 16, 2009

(54) MICROMECHANICAL SENSOR- OR ACTUATOR COMPONENT AND METHOD FOR THE PRODUCTION OF MICROMECHANICAL SENSOR- OR ACTUATOR COMPONENTS

(75) Inventors: Alexander Wolter, Dresden (DE); Thilo Sander, Dresden (DE); Harald Schenk, Dresden (DE)

Correspondence Address: COOLEY GODWARD KRONISH LLP;ATTN: Patent Group, Suite 1100, 777 - 6th Street, NW, WASHINGTON, DC, 20001, US

(73) Assignee: Fraunhofer-Gesellschaft zur Forderung der angewandten Forschung e.V., Munchen (DE)

(21) Appl. No.: 12/251,784

(22) Filed: Oct. 15, 2008

(30) Foreign Application Priority Data
Oct. 16, 2007 (DE) 1020070500027

(51) Int. Cl. G02B 26/00; H01L 21/50

(52) U.S. Cl. 359/196.1; 29/592

(57) ABSTRACT

The invention relates to a micromechanical sensor- or actuator component with an optical function and to a production method. A substrate thereby has electrodes and electrical contactings, an optical, electrically actuated element which can be deflected relative to the substrate. A transparent cover is likewise present. The object of the invention is to produce a micromechanical sensor- or actuator component with an optical function and a method for the production of such components with which to reduce or even avoid reflections which might impair the function of the micromechanical sensor- or actuator component. According to the invention, the optical main axis of the cover is thereby orientated non-perpendicular to the surface of the substrate.

The invention relates to a micromechanical sensor- or actuator component with an optical function according to the preamble of the main claim and to a method for the production of micromechanical sensor- or actuator components according to the preamble of claim 18.

There should be understood by micromechanical sensor- or actuator components with an optical function, for example scanner mirrors, scanning gratings, bolometers, photodiodes and photodiode arrays, CCD arrays, CMOS image sensors or light modulators. The components must be protected for example against contamination by particles, moisture, high energy radiation (UV, DUV) or even be operated in a vacuum. It is therefore desired that they are sealed impermeably. On the other hand, the components require at least one optical interface in order that the sensor- or actuator element which is assigned to the micromechanical sensor- or actuator component can process the incident radiation. This optical interface is produced in the known manner by a window which is transparent for the desired wavelength range of the radiation.

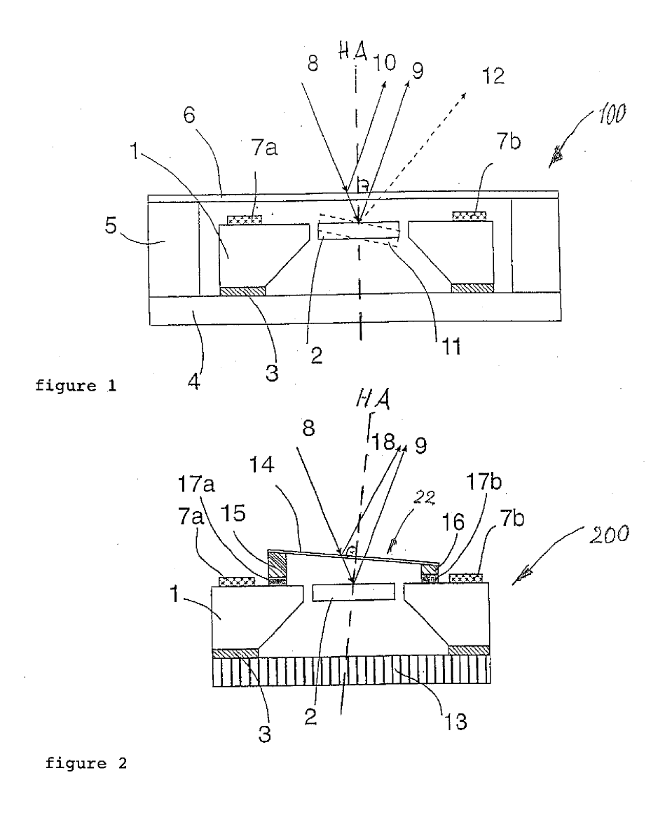

As a known example of a micromechanical sensor- or actuator component with an optical function, a micromechanical scanner mirror is represented schematically in FIG. 1 in a standard housing with a glass cover, represented in a simplified manner. The scanner mirror 100 has a substrate structure 1 to which an articulated mirror element 2 is assigned, said mirror element being configured as a mirror-coated plate and being rotatable or deflectable about an axis which is perpendicular to the drawing plane. The substrate structure 1 is connected to a housing base 4 via an adhesive layer 3. There is applied on a frame 5 of the housing, an antireflection glass cover 6 which is connected to the frame 5 for example by means of a glass solder or by means of an adhesive and has the object in particular of keeping dirt and particles away from the scanner mirror 100 or away from the substrate structure 1 and mirror element 2.

An electrical connection to electrical elements is produced on/in the housing via bond pads 7a and 7b, bonding wires and contacts not being shown in the drawing for the sake of simplification.

Such a micromechanical component represented in FIG. 1 can be produced according to various methods with respect to the covering, namely

by housing separate chips,
by wafer bonding to the covering of the chips, and
by pick & place.

Even if there are deviations in detail, the three variants can be described essentially as follows.

Firstly, individual chips which include for example the substrate structure 1, the deflectable element 2 and electrodes, not illustrated, with corresponding electrical contactings, such as the bond pads 7a, 7b, are produced by sawing, laser cutting or deliberate breaking of the wafer from which the individual chips or substrate structures are produced. Then the individual chips are inserted into a standard or special housing, e.g. by bonding, gluing or the like. Subsequently, the electrical contacting is implemented by wire bonding. Alternatively, the electrical contacting is produced with a ball-grid array on the rear side of the chip. Finally, the housing is sealed by applying a transparent cover, corresponding to a glass cover 6. With this method, a test of each chip at wafer level, i.e. before separation, can be implemented before the actual housing and covering so that only the functional chips are further processed. However, the chips must be detached from the wafer without protecting the surface by sawing, breaking or the like, which complicates the process and causes additional waste after the functional test at wafer level. A further and a substantial disadvantage is the use of relatively expensive individual housings. With wafer bonding, the wafer which contains the sensor-/actuator chips is connected to a second wafer termed cover wafer in such a manner that a whole-surface cover over the individual substrate structures or chips is produced. The cover wafer is thereby for example a glass wafer for the visible wavelength range or silicon for the IR wavelength range. If necessary, a so-called spacer is used, which ensures that a specific spacing is produced between the actual wafer and the cover wafer. This is required for example if mechanical elements of the chips present on the wafer must not be restricted in their moveability. Furthermore, a base wafer can be bonded on the rear side of the actual wafer. This is necessary for example if a vacuum is required for operation and the actual wafer is perforated. This method has the advantage that the chips are covered before separation and hence are significantly less sensitive to the separation and further processing process but also non-functional chips are covered during this method which are discarded subsequently.

With the help of pick & place machines, i.e. with positioning machines, individual covers can be placed on a wafer with high locational accuracy and precision. These placed covers can be connected to the wafer using bonding layers, such as adhesive or solder layers. This method has the advantage that the chips can be characterised and tested at wafer level before covering and then covers can be placed only on the functional chips. The functional chips intended for further processing are then significantly less sensitive, as in the method according to b), to the separation and further processing process.

Corresponding to the described state of the art, the transparent covers are always applied parallel to the chip surface in all three cases. The parallelism of cover- and chip surface presents no problem in general for pure sensors. If light or radiation is however not only coupled in but also out again, as in the case of light modulators or scanner mirrors, then, because of the parallelism of the two surfaces, i.e. of the cover 6 and of the mirror element 2 in FIG. 1, disruptive reflections occur. Antireflection layers on the upper- and underside of the cover 6 can reduce this effect but cannot entirely eliminate it. In the example corresponding to the state of the art according to FIG. 1, a two-dimensionally deflecting scanner mirror element is used for the image projection. By means of the two-dimensional deflection of the mirror element, a laser beam which is directed towards the scanner mirror 100 is guided over an image field. By modulation of the laser intensity as a function of the position of the laser spot, the desired image is produced. The laser beam is however, before it impinges on the scanner mirror, partially reflected also on the cover.

This is illustrated schematically in FIG. 1. The continuous lines show a mirror element 2 which is parallel to the chip- or substrate surface and hence is undeflected or also in its non-operative condition. A light beam passes through the transparent glass cover 6 and impinges on the mirror element 2. By means of reflection, a light beam 9 is produced. If the mirror element is deflected, as represented in FIG. 1, by the plate 11 which is illustrated in broken lines, then a light beam 12 is produced by reflection. The angle between the light beams 9 and 12 is thereby twice the angle between the illustrated mirror elements 2 and 11. The case in which the mirror element 2 is deflected by the same amount to the left as to the right is not shown. A further light beam would thereby be produced and in fact such that the light beam 9 produces precisely the angle bisection between the further light beam and light beam 12. Since the antireflection layer has a residual reflection, a further light beam 10 is produced. This has in fact a significantly lesser intensity but acts in a disruptive manner in use. Further light beams which are produced by reflection on the glass cover 6 and on the mirror element 2 are not illustrated.

If, as described above for the image projection, the scanner mirror is deflected symmetrically about its zero position, then the residual reflection on the cover corresponding to the light beam 10 causes a point in the image centre. In order to clarify the order of magnitude of this effect, it is assumed in the following that the laser is not modulated, i.e. a maximum light image field is generated. The laser intensity I is distributed for example to 640×480=307200 image points. Assuming a hundred percent transmission of the cover glass, an average intensity of I/307200 is hence allotted to each image point. With the assumption that the cover has an antireflection layer and hence has a residual reflection of 1−99.99%=0.01%, in fact an additional intensity of approx. 1/10000 is allotted in the centre to the image point. This is hence approx. 30 times as high as the intensity of the remaining image points and hence as explained, disconcerting for the observer.

The object therefore underlying the invention is to produce a micromechanical sensor- or actuator component with an optical function and a method for the production of such components with which to reduce or even avoid reflections which might impair the function of the micromechanical sensor- or actuator component.

This object is achieved according to the invention by the characterising features of the main claim and of the independent claim.

Advantageous developments and improvements are possible due to the measures indicated in the sub-claims.

As a result of the fact that the optical main axis of the cover is not perpendicular to the surface of the substrate and also does not coincide with the optical main axis of the deflectable element when inoperative, the beams which are reflected on the cover by incident light beams are not focused on one point so that no image point with a high intensity is produced. Advantageously, the cover which has normally a transparent cover element and a frame part is disposed diagonally to the surface of the substrate. Such an arrangement produces a simple construction.

It is particularly advantageous if the angle between the surface of the substrate or the surface of the deflectable element when inoperative and the cover element is greater than the maximum deflection angle of the deflectable element. Consequently, the light beam which is reflected by the cover or the cover element, at a sufficient spacing from the sensor- or actuator component, is no longer situated in a region in which the plate deflects the corresponding incident light beam. Consequently, the light beam which is reflected by the cover element can be masked for example by means of an aperture diaphragm.

The deflectable element can be configured as a plate-shaped mirror element or also as a grating. However, it can also be a hollow mirror, an optical lens or a filter element.

In a simple embodiment, the cover element is configured as a flat, single- or multilayer plate. If it is desired or required for specific applications, the cover element can be formed from one or more optical elements, such as lenses or lens arrays, prisms or the like, the optical main axis of the respective optical element or elements being situated non-perpendicular to the substrate surface. There is thereby intended by prisms, the main axis of the optically active surface upon which light can impinge, possibly also emerge there.

Advantageously, the cover can be connected to the substrate by means of an adhesion layer, the adhesion layer being able to be an adhesive layer or a solder layer but also being able to be connected to the substrate via a eutectic or SLID (solid-liquid interdiffusion).

According to requirement, the cover can be configured in one piece or also multipart, comprising in total or partially plastic material and/or being an injection moulded part.

Advantageously, the cover, on the side orientated away from the substrate, has surface elements which are configured parallel to the substrate surface. Such surface elements can be used for applying pressure by means of a workpiece, as a result of which the necessary force for the connection methods, such a for example the thermocompression method, can be applied.

It is advantageous if the substrate is connected to a base wafer as base plate, the same methods as when applying the cover being able to be used.

The method for the production of micromechanical sensor- or actuator components combines the following advantages which are known in part from the state of the art: the individual substrate structures with deflectable element and electrodes and also electrical contactings can be tested at wafer level and be encapsulated likewise at wafer level. As a result, the sensitive structures are protected during separation. The cover can have any arbitrary configuration within the prescribed conditions and the micromechanical component can be produced in total with an economical housing.

Embodiments of the invention are represented in the drawing and are explained in more detail in the subsequent description. There are shown:

FIG. 1 a micromechanical sensor- or actuator component in section according to the state of the art which is configured as a scanner mirror,

FIG. 2 a micromechanical sensor- or actuator component which is configured as a scanner mirror according to a first embodiment of the invention in section and in a schematically illustrated manner,

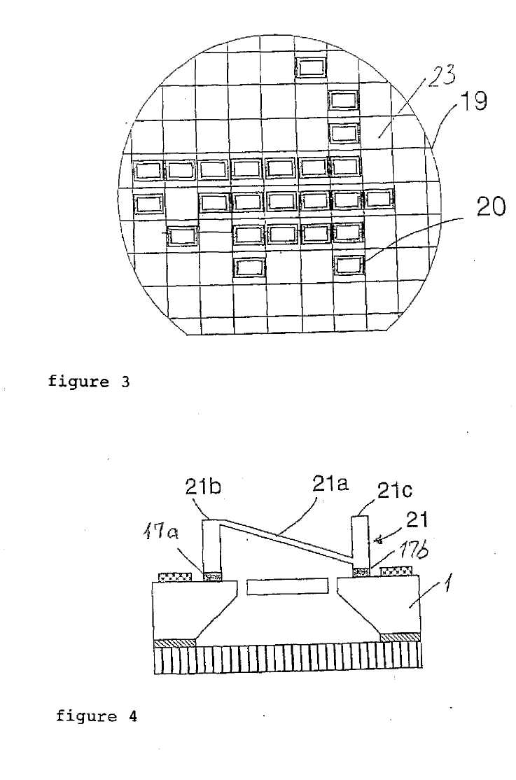

FIG. 3 a plan view on a wafer with covers applied partially on the substrate structures, and

FIG. 4 a further embodiment according to the invention of a scanner mirror as micromechanical sensor- or actuator component.

In FIG. 2, the same elements as in FIG. 1 bear the same reference numbers and therefore are no longer dealt with separately.

In FIG. 2, the part of the scanner mirror 200 which is to be protected from dirt, which part essentially relates to the deflectable element which is configured as mirror element 2, is produced from the upper side by a cover 22 which comprises a frame 15, 16 and a cover element 14 which is applied thereon. As can be detected, the frame illustrated in section has frame parts 15, 16 which have different heights. The other frame parts, not shown, are configured respectively diagonally between the frame parts 15 and 16. The transparent cover element 14 which can be produced from glass, plastic material or the like, is applied around the frame 15, 16 in such a manner that it is disposed diagonally relative to the surface of the substrate and, in the embodiment, also to the surface of the mirror element when inoperative. This tilting of the cover element 14 is chosen such that it is greater than the used maximum deflection of the mirror element 2. Since the cover element 14 and the mirror element 2 are now no longer parallel, as illustrated in FIG. 2, the beams 9 which are reflected on the mirror element 2 and the beams 18 which are reflected on the cover element are likewise no longer parallel. Since the tilting of the cover element 14 is in addition greater than the maximum deflection of the mirror element 2, the reflection produced by the light beam 18, at a sufficient spacing from the mirror element 2, is no longer in the region in which the plate deflects the light beam 8. Hence the light beam 18 can be masked for example by means of an aperture diaphragm. In FIGS. 1 and 2, the optical main axis which is perpendicular to the cover is termed main axis.

The main axis of the cover 22, 21, as evident, is not perpendicular to the surface of the substrate and hence is orientated at a diagonally inclined angle.

As can be detected from FIG. 2, the cover 22 must not cover the entire scanner mirror, it can however essentially also cover the entire substrate surface.

The underside of the substrate 1, in the embodiment according to FIG. 2, is sealed by a base wafer 13 which is connected via an adhesive layer 3 or for example also by wafer bonding to the substrate 1. A base wafer 13 is not absolutely necessary, in particular not if the sensor- or actuator element has a rear side opening.

The frame parts 15, 16 with the corresponding side parts, not shown, and hence the entire cover are connected to the surface of the substrate 1 by means of an adhesion layer 17a or 17b. The adhesion layer can comprise for example an adhesive, represent a glass solder or be produced by anodic bonding. Interdiffusion effects can also be used in order to produce a connection. Possibilities are the use of eutectics, such as Au—Si or special SLID materials.

In FIG. 4, a further embodiment of a micromechanical sensor- or actuator component is represented, the cover 21 being produced from one piece, for example from plastic material. It can be configured for example as an injection moulded part. The cover 21 has an N-shape in section which has, on the side orientated away from the substrate 1, surface elements 21b, 21c which are orientated parallel to the substrate surface. Over these surfaces, a pressure can be exerted in the wafer composite on the connection points 17a, 17b by means of a tool, said pressure being required during connecting methods, such as for example the thermocompression method, for the production of a good connection. The pressure is also very advantageous during gluing.

The N-shape illustrated in FIG. 4 can be produced alternatively also by connecting a titled glass cover with frame parts made of a different material, e.g. injection moulded materials.

In the embodiments according to FIG. 2 and FIG. 4, the cover element 21a is represented flat and plate-shaped, a plurality of layers being able to be present. It is however also conceivable for the cover element to have a more complex form. Thus for example lenses or lens arrays, prisms or other optical elements can be used.

In FIG. 3, a wafer 19 is represented, the substrate structures which are illustrated in FIGS. 1, 2 and 4 and have a deflectable element and electrodes or contactings which are provided with the reference number 23 being produced from this wafer in the known manner. These substrate structures 23 are provided unseparated on the wafer 19, covers 20 being applied on some of them. The individual substrate structures 23 or also chips were tested in advance. Cover 20 was placed only on the chips which are fully functional and hence are intended to be or can be further processed. After the test and the application of the covers 20, the individual substrate structures 23 or chips are separated from the wafer composite and then form the respective micromechanical sensor- or actuator components. The separation thereby takes place along the horizontal and vertical lines, the so-called sawing lines.

As already explained further back, the micromechanical components can be used for the most varied of applications. As scanner mirrors, they can be used in image projectors. They can thereby be configured as one- or two-dimensional scanners which can also be suitable for taking a picture. Use is also possible for confocal microscopy, e.g. as transaction mirror or OCT. Such scanner mirrors can also be used for speckle reduction.

The components according to the invention can be used with gratings also in spectrometers. Wavelength tuning of lasers or spectral imaging is likewise possible.

A configuration with Fabry-Perot filters can also be achieved with the invention, such as micromirror arrays for lithography or for projections.

Also diffractive one- or two-dimensional arrays can be configured (PCB, masks, displays).

Components with gratings, mirrors or plates can be static or deflected resonantly.

Also other diffractive optical elements can be present.

1. A micromechanical sensor- or actuator component with an optical function, comprising:
a substrate having a surface
an optical element which is deflectable relative to the substrate,
a transparent cover sealing the surface of the substrate and the deflectable optical element
wherein an optical main axis of the cover is not perpendicular to the surface of the substrate.

2. The component according to claim 1, wherein the cover has a transparent cover element and a frame part.

3. The component according to claim 2, wherein the cover element is configured as a flat, single- or multilayer plate which is preferably non-reflective coated.

4. The component according to claim 1, wherein the cover element is formed from one or more optical elements, the optical main axis of the optical element or elements not being perpendicular to the substrate surface.

5. The component according to claim 1, wherein the deflectable optical element is configured as a mirror or grating.

6. The component according to claim 1, wherein the optical deflectable element is configured for implementing a rotational movement about one or more axes.

7. The component according to claim 1, wherein the deflectable optical element is configured for implementing a translatory movement.

8. The component according to claim 1, wherein the angle between the surface of the deflectable optical element when inoperative and the cover element is greater than a maximum deflection angle of the deflectable optical element.

9. The component according to claim 1, wherein the cover is connected to the substrate by means of an adhesion layer.

10. The component according to claim 1, wherein the cover is configured to be one piece or multipart.

11. The component according to claim 1, wherein the cover, on the side orientated away from the substrate, has surface elements which are configured parallel to the substrate.

12. The component according to claim 1, wherein the cover is configured at least partially as an injection moulded part.

13. The component according to claim 1, wherein the optical element or elements are configured as lenses, lens arrays, prisms, prism arrays or the like.

14. The component according to claim 1, wherein the substrate is provided with a base plate which is configured as part of a wafer.

15. The component according to claim 14, wherein the cover and/or the base plate are connected to the substrate via an adhesive layer or a solder layer.

16. The component according to claim 14, wherein the cover and/or the base plate are connected to the substrate via a eutectic or SLID materials.

17. The component according to claim 1, wherein the deflectable optical element is actuated electrostatically, magnetically, piezoelectrically, and/or thermally.

18. A method for the production of micromechanical sensor- or actuator components which have respectively a substrate structure and a deflectable element, the substrate structures being produced with the deflectable elements from a wafer and respectively a transparent cover being placed on the individual substrate structures with assigned deflectable elements and being connected to the substrate surface and subsequently the substrate structures being separated by cutting or sawing in order to produce the micromechanical sensor- or actuator components, wherein the covers are placed on the substrate structures in such a manner that the optical main axis of the cover is not perpendicular to the substrate surface.

19. The method according to claim 18, wherein the covers are respectively glued, bonded or soldered onto the substrate surface.

20. The method according to claim 19, wherein the covers are connected respectively to the substrate surface by anodic bonding or by thermocompression bonding.

21. The method according to claim 18, wherein the covers are connected respectively to the substrate by interdiffusion using eutectics or SLID materials.

22. The method according to claim 18 the covers are positioned with the help of a template.

23. The method according to wherein a plurality of covers are positioned in the composite simultaneously.

24. The method according to claim 18, wherein the functionality of the individual substrate structures is tested before the positioning of the covers and the covers are applied only on those substrate structures which are completely functional.

25. The method according to claim 18, wherein the wafer containing the substrate structures is connected to a base wafer.

26. The method of claim 18, wherein the of micromechanical sensor- or actuator component is employed for microscopy, for beam path manipulation, for path length modulation, in scanners, in microscopes, in spectrometers, in laser displays, in laser printers, in laser exposure devices or in Fourier spectrometers.
